(19) United States
(12) Patent Application Publication
(10) Pub. No.: US 2012/0237057 A1
(43) Pub. Date: Sep. 20, 2012

(54) AUDIO DRIVER CIRCUIT

(75) Inventor: SEN-LUNG HUANG, Tu-Cheng (TW)

(73) Assignee: HON HAI PRECISION INDUSTRY CO., LTD., Tu-Cheng (TW)

(21) Appl. No.: 13/117,160

(22) Filed: May 27, 2011

(30) Foreign Application Priority Data
Mar. 18, 2011 (CN) 201110065853.X

(51) Int. Cl. H03G 3/00

(52) U.S. Cl. 381/104

(57) ABSTRACT

An audio driver circuit includes a comparison circuit, a power distributing circuit, and an audio output circuit. The comparison circuit at least includes a comparator included a non-inverting input, an inverting input, and an output. The non-inverting input is electrically connected to a drive power supply. The inverting input is electrically connected to a reference power supply. The output of the comparator is electrically connected to an input of the power distributing circuit. The audio driver circuit further includes a mute control circuit. An output of the power distributing circuit is electrically connected to the mute control circuit. An input of the audio output unit is also electrically connected to the mute control circuit.

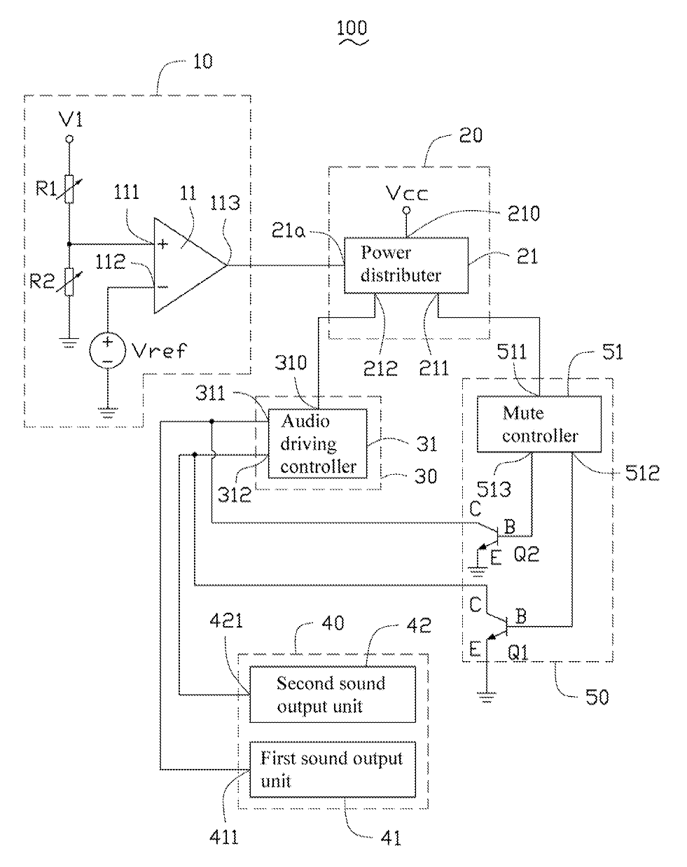

### BACKGROUND

1. Technical Field

The disclosure relates to an audio driver circuit.

2. Description of Related Art

A loudspeaker is coupled to an audio driver circuit through a coupling capacitor. When the audio driver circuit starts, an output voltage of an output of the coupling capacitor is gradually raised from zero volts to a voltage which can drive the loudspeaker. This voltage change will produce a loudspeaker noise, which often is called a “plosive.” During times when the audio driver circuit shuts off, the output voltage of the output of the coupling capacitor is gradually reduced to zero volts, this voltage change will also produce unwanted loudspeaker noise.

Therefore, it is desired to provide an audio driver circuit to overcome the above-described problem.

### BRIEF DESCRIPTION OF THE DRAWINGS

Many aspects of the present disclosure can be better understood with reference to the following drawings. The components in the drawings are not necessarily drawn to scale, the emphasis instead being placed upon clearly illustrating the principles of the present disclosure.

The drawing is a schematic view of an audio driver circuit, according to an exemplary embodiment.

### DETAILED DESCRIPTION

Embodiments of the disclosure will now be described in detail below, with reference to the drawing.

Referring to the drawing, an audio driver circuit 100, according to an exemplary embodiment, is used to drive an electronic device (not shown) to emit sound. The electronic device can be a laptop computer or a music player. The audio driver circuit 100 includes a comparison circuit 10, a power distributing circuit 20, a control circuit 30, an audio output circuit 40, and a mute control circuit 50. The comparison circuit 10 at least includes a comparator 11. The comparator 11 includes a non-inverting input 111, an inverting input 112, and an output 113. The non-inverting input 111 is electrically connected to a drive power V1. The inverting input 112 is electrically connected to a reference power supply Vref. The output 113 is electrically connected to an input of the power distributing circuit 20. An output of the power distributing circuit 20 is electrically connected to the mute control circuit 50. An input of the audio output circuit 40 is also electrically connected to the mute control circuit 50.

The comparison circuit 10 further includes a first resistor R1 and a second resistor R2. An input of the first resistor R1 is electrically connected to the drive power V1, an output of the first resistor R1 is electrically connected to an input of the second resistor R2. The non-inverting input 111 of the comparator 11 is electrically connected between the first resistor R1 and the second resistor R2. In the embodiment, both the first resistor R1 and the second resistor R2 are variable resistors.

The power distributing circuit 20 at least includes a power distributer 21. The power distributer 21 includes a control input 21a, a power input 210, a first power output 211, and a second power output 212. The control input 21a is electrically connected to the output 113 of the comparator 11. The power input 210 is electrically connected to a power supply Vcc.

The control circuit 30 at least includes an audio driving controller 31. The audio driving controller 31 includes a first power input 310, a first signal output 311, and a second signal output 312. The first power input 310 is electrically connected to the second power output 212 of the power distributer 21.

The audio output circuit 40 includes a first sound output unit 41 and a second sound output unit 42. An input 411 of the first sound output unit 41 is electrically connected to the first signal output 311 of the audio driving controller 31. An input 421 of the second sound output unit 42 is electrically connected to the second signal output 312 of the audio driving controller 31. In the embodiment, both the first sound output unit 41 and the second sound output unit 42 are loudspeakers.

The mute control circuit 50 includes a mute controller 51, a first switch Q1, and a second switch Q2. The mute controller 51 includes a first control port 511, a second control port 512, and a third control port 513. In the embodiment, both the first switch Q1 and the second switch Q2 are npn transistors. The first control port 511 of the mute controller 51 is electrically connected to the first power output 211 of the power distributer 21. A base B of the first switch Q1 is electrically connected to the second control port 512. An emitter E of the first switch Q1 is grounded. A collector C of the first switch Q1 is electrically connected to the input 411 of the first sound output unit 41. A base B of the second switch Q2 is electrically connected to the third control port 513. An emitter E of the second switch Q2 is grounded. A collector C of the second switch Q2 is electrically connected to the input 421 of the second sound output unit 42.

In the embodiment, a high logic “1” (high level voltage) is 5V and a low logic “0” (low level voltage) is 0V.

In use, during the process of the audio driver circuit 100 being turned on or being shut off, the voltage of the drive power V1 is less than that of the reference power supply Vref, the output 113 of the comparator 11 outputs a lower level voltage to the control input 21a of the power distributer 21, then the first power output 211 of the power distributer 21 outputs a high level voltage to the first control port 511 of the mute controller 51, at the same time, both the second control port 512 and the third control port 513 respectively output a high level voltage to the bases B of the first switch Q1 and the second switch Q2. The first switch Q1 and the second switch Q2 are turned on, a residual power supply provided by the first signal output 311 of the audio driving controller 31 and a residual power supply provided by the second signal output 312 of the audio driving controller 31 are lead to ground respectively through the corresponding first switch Q1 and the second switch Q2. As such, no power is provided to the first sound output unit 41 and the second sound output unit 42, and so the audio output circuit 40 is mute. In the embodiment, the reference power supply Vref is 1.23 volts.

When the audio driver circuit 100 is working normally, the voltage of the drive power V1 is greater than that of the reference power supply Vref, the output 113 of the comparator 11 outputs a high voltage to the control input 21a of the power distributer 21, then the first power output 211 of the power distributer 21 outputs a lower level voltage to the first control port 511 of the mute controller 51, and the mute controller 51 stops working. Both the first switch Q1 and the second switch Q2 are shut off. At the same time, the driving controller 31 is capable of sending sound signals to the audio output circuit 40 to drive the first sound output unit 41 and the second sound output unit 42 to emit sounds.

The number of the sound output units can be changed depending on demand as well. For example, in other embodiments, the audio output circuit 40 may include three or more sound output units.

While certain embodiments have been described and exemplified above, various other embodiments will be apparent to those skilled in the art from the foregoing disclosure. The disclosure is not limited to the particular embodiments described and exemplified, and the embodiments are capable of considerable variation and modification without departure from the scope of the appended claims.

What is claimed is:

1. An audio driver circuit, comprising:
a comparison circuit comprising a comparator, the comparator comprising a non-inverting input, an inverting input, and an output, the non-inverting input electrically connected to a drive power, the inverting input electrically connected to a reference power supply;
a mute control circuit;
a power distributing circuit comprising an input electrically connected to the output of the comparator, and an output electrically connected to the mute control circuit; and
an audio output circuit comprising at least two sound output units configured for emitting sound, each input of the at least two sound output units electrically connected to the mute control unit;
when the voltage of the drive power is less than that of the reference power supply, the output of the comparator outputs a lower level voltage to the power distributing circuit, then the power distributer outputs a high level voltage to the mute controller to control the at least two sound output units working in a mute state.

2. The audio driver circuit of claim 1, further comprising a control circuit, wherein the control circuit is electrically between an output of the power distributing circuit and inputs of the at least two sound output units, when the voltage of the drive power is greater than that of the reference power supply, the output of the comparator outputs a high voltage to the power distributing circuit, then the power distributing circuit outputs a high voltage to the control circuit to control the at least two sound output units emitting sound.

3. The audio driver circuit of claim 2, wherein the power distributing circuit comprises a power distributer, the power distributer comprises a control input, a power input, a first power output, and a second power output, the control circuit comprises an audio driving controller, the audio driving controller comprises a first power input, the mute control circuit comprises a mute controller comprising a first control port, the power input of the power distributer is electrically connected to a power supply, the first power output of the power distributer is electrically connected to the first control port of the mute controller, the second power output of the power distributer is electrically connected to is electrically connected to the second power output of the power distributer.

4. The audio driver circuit of claim 3, wherein the audio driving controller further comprises a first signal output and a second signal output, the at least two sound output units comprise a first sound output unit and a second sound output unit, the first sound output unit is electrically connected to the first signal output of the audio driving controller, the second sound output unit is electrically connected to the second signal output of the audio driving controller.

5. The audio driver circuit of claim 4, wherein the mute control circuit comprises a first switch and a second switch, both the first switch and the second switch are npn transistors, the mute controller further comprises a second control port and a third control port, a base of the first switch is electrically connected to the second control port, an emitter of the first switch is grounded, a collector of the first switch is electrically connected to a input of the first sound output unit, a base of the second switch is electrically connected to the third control port, an emitter of the second switch is grounded, a collector of the second switch is electrically connected to a input of the second sound output unit.

6. The audio driver circuit of claim 4, wherein both the first sound output unit and the second sound output unit are loudspeakers.

7. The audio driver circuit of claim 1, wherein the reference power supply is 1.23 volts.

8. The audio driver circuit of claim 1, wherein the comparison circuit further comprises a first resistor and a second resistor, an input of the first resistor is electrically connected to the drive power, an output of the first resistor is electrically connected to an input of the second resistor, the non-inverting input of the comparator is electrically connected between the first resistor and the second resistor.

9. The audio driver circuit of claim 8, wherein both the first resistor and the second resistor are variable resistors.
